(19) United States
(12) Patent Application Publication
(10) Pub. No.: US 2026/0352199 A1
(43) Pub. Date: Nov. 5, 2026

(54) JUNCTION FIELD EFFECT TRANSISTOR CASCODE CIRCUIT AND CORRESPONDING CONTROL CIRCUIT

(71) Applicant: Infineon Technologies Austria AG, Villach (AT)

(72) Inventors: Andrea PICCIONI, Villach (AT); Robert RÖSNER, Oberschleißheim (DE)

(21) Appl. No.: 19/629,660

(22) Filed: Mar. 26, 2026

(30) Foreign Application Priority Data
May 2, 2025 (DE) 102025116903.9
Feb. 27, 2026 (DE) 102026108126.6

(51) Int. Cl. H03K 17/041; G05F 1/59; H03F 3/16

(52) U.S. Cl. CPC H03K 17/04106; G05F 1/59; H03F 3/165

(57) ABSTRACT

A JFET cascode circuit includes a gate driver supplied according to a unipolar supply scheme including a supply potential, sufficient for satisfying a controlled overdrive value, and a reference potential, the gate driver configured to generate gate drive signals; a JFET having a JFET gate terminal; a voltage-controlled transistor coupled, at a cascode node, to the JFET; and an overdrive voltage circuit that includes a supply terminal at which the supply potential is provided, a reference terminal at which the reference potential is provided, and an output terminal coupled to the JFET gate terminal. The overdrive voltage circuit is configured to provide the controlled overdrive value as a fraction of the supply potential to the JFET gate terminal. The cascode node is configured to, during an off-condition, float to a higher potential than a JFET gate potential of the JFET, to set the JFET into a blocking mode.

### CROSS-REFERENCE TO RELATED APPLICATION

This application claims priority to Germany Patent Application No. 102025116903.9, filed May 2, 2025, and Germany Patent Application No. 102026108126.6, filed Feb. 27, 2026, the contents of which are incorporated herein by reference in their entireties.

### BACKGROUND

Many functions of modern devices in automotive, consumer, and industrial applications, such as driving an electric motor or an electric machine, rely on power semiconductor devices. For example, insulated gate bipolar transistors (IGBTs), metal oxide semiconductor field effect transistors (MOSFETs), and diodes, to name a few, have been used for various applications including, but not limited to, switches in power supplies, power converters, and power distribution.

Solid-state switching refers to the use of electronic components (like transistors, thyristors, or solid-state relays) instead of mechanical switches or contactors to control the flow of electrical power. Unlike traditional switches, which physically move parts to make or break a circuit, solid-state switches use semiconductor materials to do this with no moving parts.

In power distribution systems, solid-state switching often needs to block current flow in both directions (positive and negative voltages) and to conduct current in both directions (positive and negative current flow). To achieve this, two semiconductor switches are typically connected source-to-source (sometimes called a back-to-back configuration). This source-to-source configuration is a key difference from a typical power converter topology (e.g., inverter or rectifier), where the goal is usually unidirectional conduction or controlled energy transfer rather than pure bidirectional interruption.

A transistor typically comprises a semiconductor structure configured to conduct a load current along a load current path between two load terminal structures of the transistor. Further, the load current may be controlled by a control electrode, sometimes referred to as a gate electrode, of the transistor. For example, upon receiving a corresponding control signal from, for example, a gate driver, the control electrode may set its transistor in one of a conducting state or a blocking state. Accordingly, the semiconductor structure behaves like a switch with on and off states (i.e., conducting and blocking states, respectively). A load current may be controlled by driving the two complementary transistors. The amplitude of the control signal received from the gate driver for each transistor may be varied to drive the two complementary transistors between switching states. For example, a gate-source voltage VGS of a MOSFET is typically driven down to approximately zero to turn off the MOSFET and is typically driven to a maximum value to fully turn on the MOSFET. For this reason, the gate-source voltage VGS may be referred to as a control voltage.

### SUMMARY

In some implementations, a junction field effect transistor (JFET) cascode circuit includes a gate driver configured to be supplied according to a unipolar supply scheme including a supply potential, sufficient for satisfying a controlled overdrive value, and a reference potential, the gate driver configured to generate gate drive signals, including a first gate drive signal during an on-condition and a second gate drive signal during an off-condition; a JFET having a JFET gate terminal configured to control a conduction of current through the JFET according to a gate-source voltage; a voltage-controlled transistor coupled, at a cascode node, to the JFET in a cascode configuration, the voltage-controlled transistor including a transistor gate terminal coupled to the gate driver, and configured to control a conduction of current through the voltage-controlled transistor based on the first gate drive signal or the second gate drive signal; and an overdrive voltage circuit that includes a supply terminal at which the supply potential is provided, a reference terminal at which the reference potential is provided, and an output terminal coupled to the JFET gate terminal, wherein the overdrive voltage circuit is configured to generate the controlled overdrive value as a fraction of the supply potential, and output the controlled overdrive value from the output terminal to the JFET gate terminal, and wherein the cascode node is configured to, during the off-condition, float to a higher potential than a JFET gate potential of the JFET, to set the JFET into a blocking mode.

In some implementations, a JFET cascode circuit includes a gate driver configured to be supplied according to a unipolar supply scheme including a supply potential, sufficient for satisfying a controlled overdrive voltage, and a reference potential, the gate driver configured to generate gate drive signals, including a first gate drive signal during an on-condition and a second gate drive signal during an off-condition; a JFET having a JFET gate terminal configured to control a conduction of current through the JFET according to a gate-source voltage; a voltage-controlled transistor coupled, at a cascode node, to the JFET in a cascode configuration, the voltage-controlled transistor including a transistor gate terminal coupled to the gate driver, and configured to control a conduction of current through the voltage-controlled transistor based on the first gate drive signal or the second gate drive signal; and an overdrive voltage circuit that includes a supply terminal at which the supply potential is provided, a reference terminal at which the reference potential is provided, and an output terminal coupled to the JFET gate terminal and from which the controlled overdrive voltage is provided, wherein the overdrive voltage circuit is configured to set the controlled overdrive voltage to a predetermined amount of the supply potential, and wherein the cascode node is configured to, during the off-condition, float to a higher potential than a JFET gate potential of the JFET, to set the JFET into a blocking mode.

A junction field effect transistor (JFET) cascode control circuit is provided. The JFET cascode control circuit is configured to control a JFET cascode circuit. The JFET cascode circuit comprises a voltage-controlled transistor coupled to a JFET in a cascode configuration. In some implementations, the JFET cascode control circuit comprises: a gate driver configured to be supplied according to a unipolar supply scheme including a supply potential, sufficient for satisfying a controlled overdrive value, and a reference potential, the gate driver configured to generate gate drive signals based on a control signal, including a first gate drive signal during an on-condition and a second gate drive signal during an off-condition, and to output the first gate drive signal or the second gate drive signal at a gate drive terminal configured to be coupled to transistor gate terminal of the voltage-controlled transistor; an overdrive voltage circuit that includes a supply terminal at which the supply potential is provided, a reference terminal at which the reference potential is provided, and an output terminal configured to be coupled to a JFET gate terminal of the JFET, wherein the overdrive voltage circuit is configured to generate the controlled overdrive value as a fraction of the supply potential, and output the controlled overdrive value from the output terminal to the JFET gate terminal.

### BRIEF DESCRIPTION OF THE DRAWINGS

Implementations are described herein making reference to the appended drawings.

FIG. 1 shows a graph of drain-to-source on resistance (RDSon) vs. VGS of an n-channel high-voltage (HV)-JFET.

FIG. 2 shows an assembly of a power switch and a clamping element.

FIG. 3 is a schematic block diagram illustrating a JFET cascode circuit according to one or more implementations.

FIG. 4A shows an overdrive voltage circuit according to one or more implementations.

FIG. 4B shows an overdrive voltage circuit according to one or more implementations.

FIG. 5 is a schematic block diagram illustrating a JFET cascode circuit according to one or more implementations.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

A transistor can be referred to as a power switch, a power semiconductor, a logic switch, or a transistor switch that may be used to drive a current, such as a load current. In particular, a power transistor is a power semiconductor device that may be used to drive a load current. The power transistor includes a first load terminal (e.g., a source or an emitter) and a second load terminal (e.g., a drain or a collector). Additionally, a load current path of the power transistor may be controlled by a control electrode, sometimes referred to as a gate, connected to a control terminal of the power transistor. A load current path of the power transistor is a gate-controlled conductive channel whose conductivity may be controlled by a control voltage applied to the control electrode of the power transistor. For example, the power transistor can be turned on or off by activating and deactivating its control electrode. For example, applying a positive voltage across a gate and a source of a MOSFET will keep the MOSFET in its “on” state, while applying a voltage of approximately zero or slightly negative across the gate and the source of the MOSFET will cause the MOSFET to turn “off.” As used herein, “on-state,” “on-condition,” “steady-state on-condition,” “current-conduction state,” “conduction mode,” and the like may be used interchangeably to refer to an on-state of a transistor. Additionally, “off-state,” “off-condition,” “current-blocking state,” “blocking mode,” and the like may be used interchangeably to refer to an off-state of a transistor.

There is a turn-on process and a turn-off process for switching a transistor on and off. During the turn-on process of an n-channel transistor, a gate driver may be used to provide (source) a gate current (e.g., an ON current) to a gate of the n-channel transistor in order to charge a gate voltage to a sufficient voltage to turn on the n-channel transistor. In contrast, during the turn-off process of the n-channel transistor, the gate driver is used to draw (sink) a gate current (e.g., an OFF current) from the gate of the n-channel transistor in order to discharge the gate voltage sufficiently to turn off the n-channel transistor. A voltage pulse may be output from the gate driver as a control signal according to a pulse-width modulation (PWM) scheme. Thus, the control signal may be switched between an ON voltage level and an OFF voltage level during a PWM cycle for controlling the n-channel transistor. This in turn charges and discharges gate capacitance to correspondingly modulate the gate voltage to turn on and off the n-channel transistor, respectively.

The opposite is true for a p-channel transistor. The gate driver may be used to draw (sink) a gate current (e.g., an ON current) from a gate of the p-channel transistor in order to discharge the gate voltage to a sufficient voltage to turn on the p-channel transistor. In contrast, during the turn-off process of the p-channel transistor, the gate driver is used to provide (source) a gate current (e.g., an OFF current) to the gate of the p-channel transistor in order to charge the gate voltage of the p-channel transistor sufficiently to turn off the p-channel transistor. A control signal applied to the gate of the p-channel transistor may be switched between an ON voltage level and an OFF voltage level during a PWM cycle for controlling the p-channel transistor. This in turn charges and discharges the gate voltage to turn on and off the p-channel transistor, respectively.

For both n-channel and p-channel transistors, the n-channel and p-channel transistors are off when the gate-source voltage VGS is approximately a zero value or below a threshold voltage and the n-channel and p-channel transistors are on when the gate-source voltage VGS is equal to or greater than the threshold voltage.

Another type of transistor is a junction field effect transistor (JFET). An n-channel JFET as a standalone element is a normally-on device. In order to turn-off the n-channel JFET, a negative voltage between the gate and the source contact of the n-channel JFET has to be applied (e.g., a negative VGS, where the source has a higher potential than the gate). In some applications, a normally-off behavior of the power stage is required (e.g., a connection between drain and source is in a high-impedance state while no active control signal is applied at the gate). In other applications, the introduction of negative control voltages, which would be required to put an n-channel JFET into a high-impedance state (off-state) is not practical or desired. In both cases, a JFET can be applied in series-connection with a normally-off device, such as a standard enhancement-type MOSFET, to meet design requirements. A circuit topology in which a JFET is connected in series with a normally-off device is known as a JFET cascode. However, certain characteristics of the JFET cascode must be considered in order to optimize performance of the JFET cascode.

In solid state power distribution applications, a total path resistance (e.g., drain-to-source on resistance (RDSon)) of a power stage is important. In this case, a minimal possible RDSon of a JFET may be achieved by a gate control circuit. For example, by controlling a gate-to-source voltage of the JFET during an on-state, the RDSon of the JFET may be controlled.

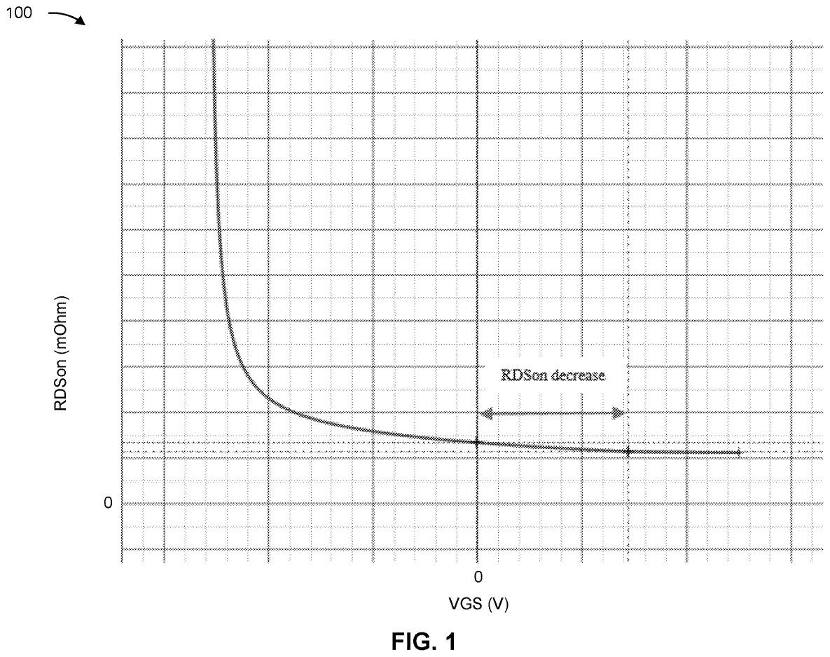

FIG. 1 shows a graph 100 of RDSon vs. VGS of an n-channel high-voltage (HV)-JFET. Some n-channel power JFETs exhibit a pronounced gate-source voltage VGS dependency of the RDSon value around VGS=0V. The application of a positive VGS further reduces a channel RDSon relative to an RDSon value present at VGS=0V. In the example illustrated in the graph 100, a 17% decrease in the RDSon may be realized by applying a positive VGS compared to the RDSon at which VGS=0V. Thus, a positive VGS may be referred to as an overdrive voltage, an overdrive gate voltage, an overdrive VGS, or an overdrive value. In other words, an overdrive voltage is a positive voltage between the gate and the source of the JFET at which RDSon is further reduced compared to VGS being equal to 0V. Due to the structure of an n-channel JFET, a maximum applicable gate voltage is limited by the JFET's intrinsic gate-to-source pn junction and gate-to-drain pn junction. For example, once the VGS or a gate-drain voltage VGD exceed a certain voltage, such as a knee voltage, of the respective intrinsic pn junction, the intrinsic gate-to-source pn junction and gate-to-drain pn junction start to conduct high levels of gate current. The knee voltage (also called the threshold voltage) of an intrinsic pn junction is the minimum forward voltage at which the pn junction starts to conduct significantly. For example, for a silicon pn junction, the knee voltage is typically between 0.6 V and 0.7 V, and for a silicon carbide (SiC) pn junction, the knee voltage is typically between about 2.5V and 3V (note that the knee voltage of a specific intrinsic pn junction may depend on device characteristics, such as doping levels, and on temperature, for example). Conducting high levels of gate current by the intrinsic gate-to-source pn junction and gate-to-drain pn junction is not desired, as the currents through these intrinsic pn junction structures increases the power dissipation in the JFET and loads a gate driver's power supply. Furthermore, a saturation effect of d(RDSon)/d(VGS) is seen once a VGS voltage level exceeds the knee voltage of the gate-to-source pn junction and the gate-to-drain pn junction. Therefore, it may be preferred, during a steady-state on condition of the JFET (e.g., while the JFET is in an on-state) to drive the VGS level of the JFET (e.g., the overdrive voltage) close to the knee voltage level of the intrinsic pn junctions to achieve a minimum RDSon while keeping a steady-state gate current at a low level.

Transistor chip sizes applied in some applications (e.g., solid-state power distribution) can be large to achieve a desired low RDSon (e.g., <1 mOhm at VBDss ratings of 1200V, where VBDss refers to a drain-source breakdown voltage). Hence, a total gate charge (mainly a gate-drain charge (Qgd)) of JFET devices can be very high, easily exceeding 1000 nanocoulombs (nC). In order to achieve a reasonable fast switching behavior of a JFET device (dV/dt>1 kV/μs), high transient gate currents are required, which may exceed levels of 10 A. On top, high transient current capability of a gate drive circuit has to be enabled to maintain safe control of the power device during voltage transients applied across a JFET's drain-source contacts (e.g., during switching transients of an external airgap device). Therefore, it may be essential to implement a very low-impedance drive circuit for the JFET gate.

While, due to the large transistor size, the transient gate drive currents can be substantial, an average gate drive current consumption in applications of solid-state power distribution applications can be very low since the JFET operates at low switching frequencies (e.g., operating frequencies are <<1 Hz). Therefore, it is important to reduce leakage currents that are continuously fed into the JFET gate to a minimum value in order to reduce the effort of the power supply scheme for the gate drive circuit.

Shutdown current levels (current densities) applied in solid state power distribution applications can be very high, close to the specified absolute maximum pulse current levels of the power devices. Furthermore, the energy stored in the residual line/load inductance of an external circuit is absorbed by a clamping element and partly by the JFET itself.

In case of an overcurrent shutdown, a power semiconductor has to support the commutation of a shutdown current into the clamping element (e.g., a varistor (MOV), a transient voltage suppressor (TVS), a resistor-capacitor (RC)-network, or the like). As soon as the commutation is completed, the power semiconductor has to block the clamping voltage of the clamping element.

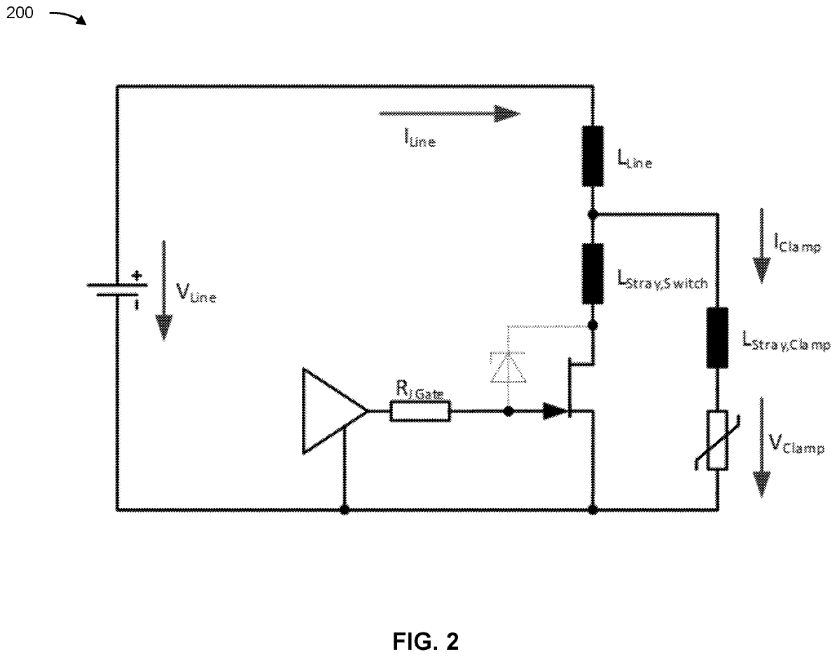

FIG. 2 shows an assembly 200 of a power switch (e.g., a JFET) and a clamping element. Both the JFET as well as the clamping element have an in-series parasitic stray inductance Lstray, Switch and LStray, Clamp, respectively. In order to achieve a successful commutation, the JFET has to provide a blocking voltage that is higher than a steady-state clamping voltage of the clamping element. The blocking voltage during commutation can be calculated by Equation 1.

V_{DS,Semiconductor}=V_{clamp}+(L_{stray,Switch}+L_{Stray,Clamp})*d(I_{Clamp})/dt (1)

While with conventional switching devices, such as MOSFETs, the switching speed of the output stage is set by control measures (e.g., increasing the gate resistance) to avoid exceeding the specified maximum VBDss of the power device, n-channel power JFET devices can be operated in an unclamped inductive switching (UIS) mode. In this way, the internal drain-gate diode is utilized to drive the JFET into linear mode and provide a controlled VDS voltage at or above a specified maximum VBDss voltage. This clamping mode must be enabled by a dedicated gate control scheme. Linear mode is achieved through the drain-gate pn junction avalanche breakdown current causing a voltage drop in the gate resistance network.

Some implementations disclosed herein are directed to a JFET cascode circuit that provides a highly efficient way of driving a discrete JFET cascode that provides a best possible RDSon at minimal circuit complexity, a required gate-drive strength, and a minimized steady-state supply current consumption. The JFET cascode circuit includes a JFET and a voltage-controlled transistor, such as a MOSFET, coupled to the JFET in a cascode configuration. For example, in the cascode configuration, a source terminal of the JFET may be coupled to a drain terminal of the voltage-controlled transistor at a cascode node. The voltage-controlled transistor may be driven to control a potential at the cascode node to place the JFET into either a current-conduction mode or a blocking mode. For example, when the voltage-controlled transistor is in the blocking mode, the cascode node may be configured to float to a higher potential than a JFET gate potential of the JFET (e.g., making VGS negative) to set the JFET into a blocking mode. Conversely, when the voltage-controlled transistor is in the current-conduction mode, a potential at the cascode node may be pulled down by the voltage-controlled transistor such that VGS is sufficient to set the JFET into a current-conduction mode. Thus, an on/off state of the JFET is indirectly controlled by controlling the on/off state of the voltage-controlled transistor, with the JFET being on based on the voltage-controlled transistor being on, and the JFET being off based on the voltage-controlled transistor being off. In the case where an overdrive signal (e.g., an overdrive potential) is applied to the gate of the JFET, the VGS of the JFET will be positive when the voltage-controlled transistor is in the current-conduction mode, thereby achieving an overdrive VGS to lower the RDSon of the JFET.

In some implementations, a JFET gate drive voltage is derived from a supply potential configured to provide a gate driver by an overdrive voltage circuit. The voltage provided to the JFET gate by the overdrive voltage circuit element is limited or otherwise regulated by the overdrive voltage circuit to a level below a knee voltage of an intrinsic GS pn junction of the JFET. Due to the control of the JFET gate drive voltage, an applied VGS overdrive voltage can be set such that a reduced or a minimum RDSon can be achieved at the JFET (e.g., to a predefined reduced RDSon value), while a forward current into the intrinsic GS pn junction of the JFET is limited to a predefined current value. A current limiting element RJGATE placed between an output of the voltage limiter and the JFET gate is not required to limit the current fed into the JFET gate in a steady-state on-condition, but can be provided and sized to optimize the switching performance of the JFET, and to maintain stable operation in case of external distortions.

The gate driver includes a buffer configured to generate gate drive signal. The buffer may include a pair of complementary FETs used to generate the gate drive signal. For example, one FET (e.g., a source FET) may be connected to a positive supply potential and, when enabled, pulls the gate drive signal up toward the positive supply potential (e.g., a high level). The other FET (e.g., a sink FET) may be connected to a reference potential (e.g., a ground potential) and, when enabled, pulls the gate drive signal down toward the reference potential (e.g., a low level). When enabled, the source FET may generate an on current Io+ (e.g., a source current) to charge a gate of a transistor for turning on the transistor. When enabled, the sink FET may generate an off current Io− (e.g., a sink current) to discharge the gate of a transistor for turning off the transistor.

Thus, the gate driver is supplied according to a unipolar supply scheme that uses only one power rail (e.g., +12V) and a single ground/reference (e.g., 0V). All voltages in the system are positive (or zero) relative to the ground of the unipolar supply scheme. In other words, all voltage potentials in the circuit swing in only one polarity (e.g., positive) with respect to ground. As a result, the JFET cascode circuit is simplified relative to gate driver circuits that use a multiple supply scheme that has two or more positive supplies and/or two or more reference supplies, one of which may be negative.

The JFET cascode circuit may be turned off by the gate driver by setting the voltage-controlled transistor into a blocking mode. Due to a blocking channel of the voltage-controlled transistor, a source potential of the JFET floats high causing a negative VGS voltage required to transition the JFET into blocking mode.

A steady-state drive current of JFET cascode circuit arrangement is minimized to a leakage current of a gate of the voltage-controlled transistor and the JFET gate. Since a switching frequency of typical solid state power distribution applications is very low, the JFET cascode circuit allows coreless transformers to be used as a supply element, which may be important for reducing the size and cost of solid-state circuit breaker (SSCB) implementations.

Moreover, the JFET cascode circuit provides a very low-ohmic gate drive solution, enabling safe and stable operation of the JFET while minimizing the gate drive current requirements and still achieve a best possible RDSon in on-mode (e.g., during the steady-state on-condition of the JFET).

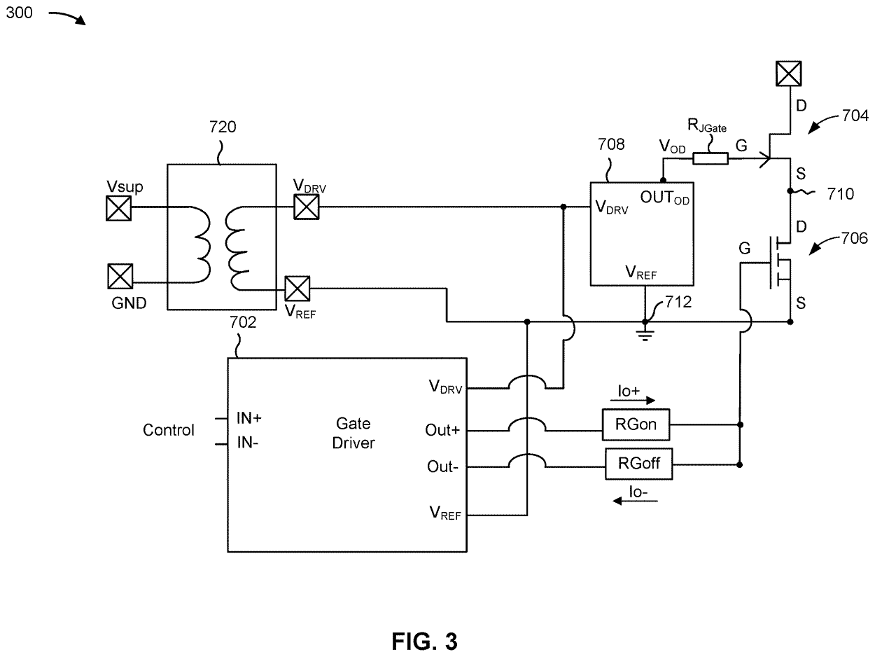

FIG. 3 is a schematic block diagram illustrating a JFET cascode circuit 300 according to one or more implementations. The JFET cascode circuit 300 may include a gate driver 702, a JFET 704, a voltage-controlled transistor 706, and an overdrive voltage circuit 708. The JFET 704 may be an n-channel HV JFET, and the voltage-controlled transistor 706 may be an n-channel LV MOSFET.

The gate driver 702 is configured to be supplied according to a unipolar supply scheme. The unipolar supply scheme includes a supply potential VDRV (e.g., a single supply potential, such as +12V), sufficient for satisfying a controlled overdrive value (e.g., a controlled overdrive voltage), and a reference potential VREF (e.g., a single reference potential, such as 0V or ground). The gate driver 702 is configured to generate gate drive signals, including a first gate drive signal during an on-condition and a second gate drive signal during an off-condition. For example, the gate driver 702 may generate the first gate drive signal at a first gate drive terminal Out+ and may generate the second gate drive signal at a second gate drive terminal Out−. In some implementations, the first gate drive signal may be an on current Io+ (e.g., a source current) and the second gate drive signal may be an off current Io− (e.g., a sink current). The gate drive signals may be based on one or more control signals received from a controller. For example, the gate driver 702 may receive a first PWM control signal at a first input terminal IN+, and may receive a second PWM control signal at a second input terminal IN−. The first PWM control signal may be used to control a source FET of the gate driver 702, for generating the first gate drive signal, and the second PWM control signal may be used to control a sink FET of the gate driver 702, for generating the second gate drive signal.

The JFET 704 includes a JFET gate terminal (G) configured to control a conduction of current through the JFET according to a gate-source voltage VGS. The voltage-controlled transistor 706 is coupled to the JFET 704 in a cascode configuration. For example, a source terminal (S) of the JFET 704 may be coupled to a drain terminal (D) of the voltage-controlled transistor 706 at a cascode node 710 to form the cascode configuration. A source terminal (S) of the voltage-controlled transistor 706 may be coupled to a common source node 712 of the JFET cascode circuit 300, where the common source node 712 is coupled to the reference potential VREF. Thus, the source terminal (S) of the voltage-controlled transistor 706 may be grounded.

The voltage-controlled transistor 706 includes a transistor gate terminal (G) coupled to the first gate drive terminal Out+ and the second gate drive terminal Out− of the gate driver 702. The transistor gate terminal of the voltage-controlled transistor 706 is configured to control a conduction of current through the voltage-controlled transistor 706 based on the first gate drive signal or the second gate drive signal. For example, during an on-condition, the on current Io+ may flow through gate resistor RGon to charge the gate of the voltage-controlled transistor 706. Alternatively, during an off-condition, the off current Io− may flow through gate resistor RGoff to discharge the gate of the voltage-controlled transistor 706. In other words, the gate driver 702 may source the first gate drive signal from the first gate drive terminal Out+ to the transistor gate terminal of the voltage-controlled transistor 706 during the on-condition, and may sink the second gate drive signal from the transistor gate terminal of the voltage-controlled transistor 706 to the second gate drive terminal Out− during the off-condition.

The overdrive voltage circuit 708 may include a supply terminal at which the supply potential VDRV is provided, a reference terminal at which the reference potential VREF is provided, and an output terminal OUTOD coupled to the JFET gate terminal of the JFET 704. The overdrive voltage circuit 708 may generate the controlled overdrive value as a fraction of the supply potential VDRV, and output the controlled overdrive value from the output terminal OUTOD to the JFET gate terminal. In some implementations, the overdrive voltage circuit 708 may generate the controlled overdrive value as a fixed, preset value (e.g., a predetermined amount of the supply potential VDRV). Thus, the JFET gate potential may be limited according to a controlled overdrive potential VOD provided by the overdrive voltage circuit 708. In some implementations, the overdrive voltage circuit 708 may be configured to generate the controlled overdrive value such that the JFET gate terminal of the JFET 704 is always biased during operation (e.g., during the on-condition and the off-condition) with a positive potential.

The overdrive voltage circuit 708 may include a plurality of passive and/or active elements in a specific arrangement configured to provide a controlled overdrive voltage. Example passive elements are resistors or diodes. Example active elements are transistors or thyristors. For example, the overdrive voltage circuit 708 may be implemented as a voltage divider using resistors and/or diodes. Alternatively, the overdrive voltage circuit 708 may be implemented as a voltage regulator, such as a low-dropout regulator or a switching regulator.

The cascode node 710 may be configured to, during the off-condition, float to a higher potential than a JFET gate potential of the JFET 704, to set the JFET 704 into a blocking mode. For example, the gate driver 702 may, during the off-condition, set the voltage-controlled transistor 706 into the blocking mode such that the cascode node 710 is at the higher potential than the JFET gate potential, and the gate-source voltage VGS of the JFET 704 is sufficiently negative to set the JFET 704 into the blocking mode. In some implementations, the gate driver 702 may, during the off-condition, set the voltage-controlled transistor 706 into the blocking mode such that the cascode node 710 is at the higher potential than the controlled overdrive value, and the gate-source voltage VGS of the JFET 704 is sufficiently negative to set the JFET 704 into the blocking mode.

In addition, the gate driver 702 may, during the on-condition, set the voltage-controlled transistor 706 into a conduction mode such that the cascode node 710 is at a lower potential than the JFET gate potential to cause the gate-source voltage VGS of the JFET 704 to be sufficient to set the JFET 704 into a conduction mode. The overdrive voltage circuit 708 may limit the controlled overdrive value at the output terminal OUTOD to a positive value that causes a drain-to-source on resistance RDSon of the JFET 704 to be reduced or minimized. In some implementations, the overdrive voltage circuit 708 may limit the controlled overdrive value to a positive value that is less than a knee voltage of a gate-to-source pn junction of the JFET 704. Thus, the overdrive voltage circuit 708 may limit the controlled overdrive value at the output terminal OUTOD to a positive value that causes a drain-to-source on resistance RDSon of the JFET 704 to be minimized or to be set to a predefined value without a controlled overdrive VGS exceeding the knee voltage of the gate-to-source pn junction of the JFET 704. Thus, the controlled overdrive value may be a positive value that is less than the knee voltage of the gate-to-source pn junction of the JFET 704. In some implementations, the controlled overdrive value may be a voltage level at which the RDSon of the JFET 704 is minimized without the voltage level exceeding the knee voltage of the gate-to-source pn junction. The overdrive voltage circuit 708 may, during the on-condition, limit a forward current flowing into the gate-to-source pn junction of the JFET 704 to a predefined value.

In some implementations, the overdrive voltage circuit 708 may, during the on-condition and the off-condition, bias the JFET gate terminal according to the controlled overdrive value. For example, the overdrive voltage circuit 708 may be a voltage divider configured to continuously provide a desired overdrive value (e.g., the controlled overdrive value) during the on-condition and the off-condition, leading to a permanent positive bias at the JFET gate terminal during the on-condition and the off-condition. Alternatively, the overdrive voltage circuit 708 may be a voltage regulator configured to continuously provide the controlled overdrive value during the on-condition and the off-condition, leading to a permanent positive bias at the JFET gate terminal during the on-condition and the off-condition.

In some implementations, the reference terminal of the overdrive voltage circuit 708 may be coupled to the common source node 712 of the JFET cascode circuit 300, at which the reference potential VREF is provided. The common source node 712 may correspond to a source terminal of the voltage-controlled transistor 706. Alternatively, in some implementations, the reference terminal of the overdrive voltage circuit 708 may be coupled to the cascode node 710 of the JFET cascode circuit 300.

As described above, the gate driver 702 is configured to be supplied according to a unipolar supply scheme. The unipolar supply scheme may include a transformer 720 with a primary side coil connected to a supply potential Vsup and ground potential GND, and a secondary side coil connected to the supply potential VDRV and the reference potential VREF. The primary side coil and the secondary side coil may have a turns ratio, with the secondary side coil having a predetermined number of turns. Of course, the unipolar supply scheme may include further circuitry with active and/or passive elements (not shown), for example to rectify a signal transmitted via the transformer 720.

As indicated above, FIG. 3 is provided merely as an example. Other examples may differ from what is described with regard to FIG. 3.

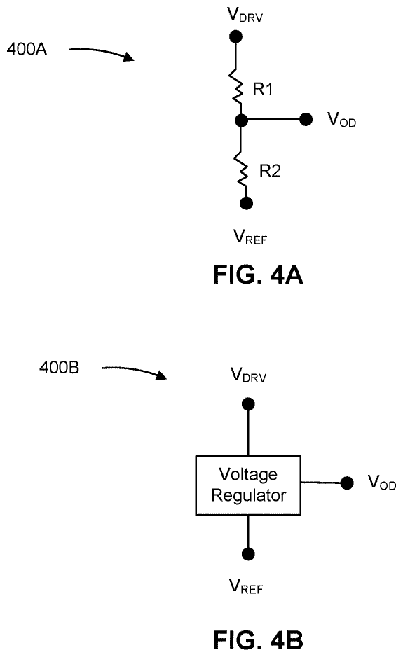

FIG. 4A shows an overdrive voltage circuit 400A according to one or more implementations. The overdrive voltage circuit 400A may be implemented as the overdrive voltage circuit 708 described in connection with FIG. 3. The overdrive voltage circuit 400A may include a supply terminal at which the supply potential VDRV is provided, a reference terminal at which the reference potential VREF is provided, and an output terminal. The output terminal may be coupled to a JFET gate terminal of a JFET, as described above. The overdrive voltage circuit 708 may generate a controlled overdrive potential VOD as a fraction of the supply potential VDRV, and output the controlled overdrive potential VOD from the output terminal. The overdrive voltage circuit 708 may include two or more resistors (e.g., resistors R1 and R2) arranged in a voltage divider configuration for producing the controlled overdrive potential VOD as a fraction of the supply potential VDRV.

As indicated above, FIG. 4A is provided merely as an example. Other examples may differ from what is described with regard to FIG. 4A.

FIG. 4B shows an overdrive voltage circuit 400B according to one or more implementations. The overdrive voltage circuit 400B may be implemented as the overdrive voltage circuit 708 described in connection with FIG. 3. The overdrive voltage circuit 400B may include a supply terminal at which the supply potential VDRV is provided, a reference terminal at which the reference potential VREF is provided, and an output terminal. The output terminal may be coupled to a JFET gate terminal of a JFET, as described above. The overdrive voltage circuit 708 may generate a controlled overdrive potential VOD as a fraction of the supply potential VDRV, and output the controlled overdrive potential VOD from the output terminal. The overdrive voltage circuit 708 may be a voltage regulator, such as a low-dropout regulator or a switching regulator, that produces the controlled overdrive potential VOD as a fraction of the supply potential VDRV.

As indicated above, FIG. 4B is provided merely as an example. Other examples may differ from what is described with regard to FIG. 4B.

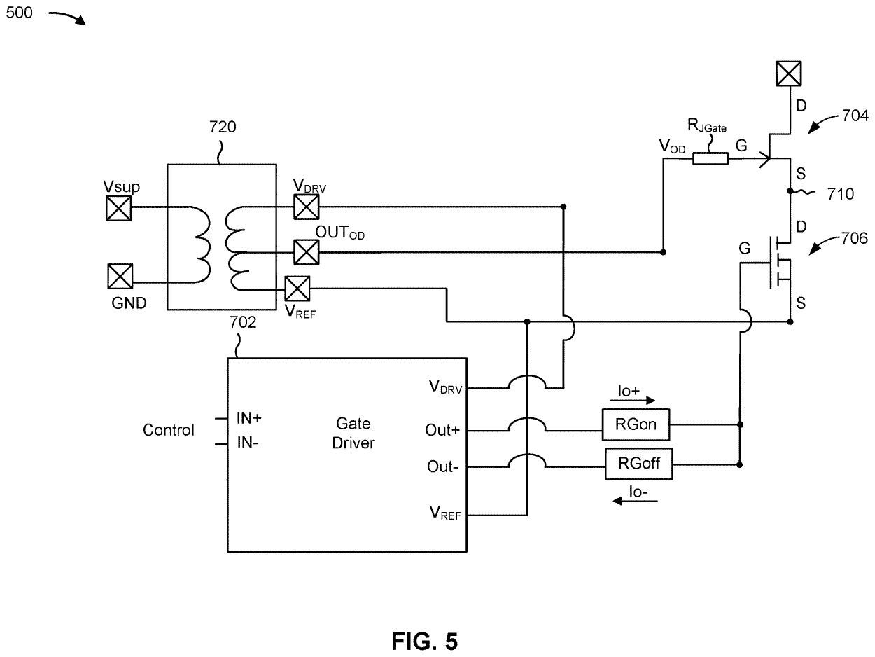

FIG. 5 is a schematic block diagram illustrating a JFET cascode circuit 500 according to one or more implementations. The JFET cascode circuit 500 may be similar to the JFET cascode circuit 300 described in connection with FIG. 3. However, instead of using the overdrive voltage circuit 708 to limit the controlled overdrive value at the output terminal OUTOD, the output terminal OUTOD is connected to a middle tap of the transformer 720 (e.g., a middle tap of the secondary side coil) for providing the controlled overdrive potential VOD. Thus, the transformer 720 may be an overdrive voltage circuit that generates the controlled overdrive potential VOD as a fraction of the supply potential VDRV, and outputs the controlled overdrive potential VOD from the output terminal OUTOD. For example, the middle tap of the secondary side coil may be used to directly provide the desired overdrive potential VOD. The controlled overdrive potential VOD may be tapped at a middle position the secondary side coil that corresponds to a lower number of turns. In some implementations, the middle position may be adjustable in order to obtain the overdrive potential VOD.

Thus, the transformer 720 may supply the gate driver 702 according to the unipolar supply scheme, wherein the transformer 720 includes the primary side coil and the secondary side coil, wherein the supply terminal, the reference terminal, and the output terminal are coupled to the secondary side coil, with the output terminal OUTOD being coupled to the secondary side coil at a middle tap position between the supply terminal and the reference terminal. The transformer 720 may generate the controlled overdrive value (e.g., the overdrive potential VOD) as a fraction of the supply potential VDRV, and output the controlled overdrive value from the output terminal OUTOD to the JFET gate terminal.

In some implementations, the gate driver 702 may, during the off-condition, set the voltage-controlled transistor 706 into the blocking mode such that the cascode node 710 is at the higher potential than the controlled overdrive value, and the gate-source voltage VGS of the JFET 704 is sufficiently negative to set the JFET 704 into the blocking mode. In addition, the gate driver 702 may, during the on-condition, set the voltage-controlled transistor 706 into a conduction mode such that the cascode node 710 is at a lower potential than the JFET gate potential to cause the gate-source voltage VGS of the JFET 704 to be sufficient to set the JFET 704 into a conduction mode.

The transformer 720 may be configured to limit or otherwise provide the controlled overdrive value at the output terminal OUTOD to a positive value that causes a drain-to-source on resistance RDSon of the JFET 704 to be reduced or minimized. In some implementations, the transformer 720 may be configured to limit the controlled overdrive value to a positive value that is less than a knee voltage of a gate-to-source pn junction of the JFET 704. Thus, the transformer 720 may be configured to limit the controlled overdrive value at the output terminal OUTOD to a positive value that causes a drain-to-source on resistance RDSon of the JFET 704 to be minimized or to be set to a predefined value without a controlled overdrive VGS exceeding the knee voltage of the gate-to-source pn junction of the JFET 704. Thus, the controlled overdrive value may be a positive value that is less than the knee voltage of the gate-to-source pn junction of the JFET 704. In some implementations, the controlled overdrive value may be a voltage level at which the RDSon of the JFET 704 is minimized without the voltage level exceeding the knee voltage of the gate-to-source pn junction. The transformer 720 may be configured to, during the on-condition, limit a forward current flowing into the gate-to-source pn junction of the JFET 704 to a predefined value.

In some implementations, the transformer 720 may be configured to, during the on-condition and the off-condition, bias the JFET gate terminal according to the controlled overdrive value. For example, the transformer 720 may be configured to continuously provide the controlled overdrive value during the on-condition and the off-condition, leading to a permanent positive bias at the JFET gate terminal during the on-condition and the off-condition.

As indicated above, FIG. 5 is provided merely as an example. Other examples may differ from what is described with regard to FIG. 5.

The following provides an overview of some Aspects of the present disclosure:

Aspect 1: A JFET cascode circuit, comprising: a gate driver configured to be supplied according to a unipolar supply scheme including a supply potential, sufficient for satisfying a controlled overdrive value, and a reference potential, the gate driver configured to generate gate drive signals, including a first gate drive signal during an on-condition and a second gate drive signal during an off-condition; a JFET having a JFET gate terminal configured to control a conduction of current through the JFET according to a gate-source voltage; a voltage-controlled transistor coupled, at a cascode node, to the JFET in a cascode configuration, the voltage-controlled transistor including a transistor gate terminal coupled to the gate driver, and configured to control a conduction of current through the voltage-controlled transistor based on the first gate drive signal or the second gate drive signal; and an overdrive voltage circuit that includes a supply terminal at which the supply potential is provided, a reference terminal at which the reference potential is provided, and an output terminal coupled to the JFET gate terminal, wherein the overdrive voltage circuit is configured to generate the controlled overdrive value as a fraction of the supply potential, and output the controlled overdrive value from the output terminal to the JFET gate terminal, and wherein the cascode node is configured to, during the off-condition, float to a higher potential than a JFET gate potential of the JFET, to set the JFET into a blocking mode.

Aspect 2: The JFET cascode circuit of Aspect 1, wherein the gate driver is configured to, during the off-condition, set the voltage-controlled transistor into the blocking mode such that: the cascode node is at the higher potential than the JFET gate potential, and the gate-source voltage is sufficiently negative to set the JFET into the blocking mode.

Aspect 3: The JFET cascode circuit of Aspect 2, wherein the gate driver is configured to, during the on-condition, set the voltage-controlled transistor into a conduction mode such that the cascode node is at a lower potential than the JFET gate potential to cause the gate-source voltage to be sufficient to set the JFET into a conduction mode, and wherein the overdrive voltage circuit is configured to limit the controlled overdrive value to a positive value that causes a drain-to-source on resistance of the JFET to be minimized.

Aspect 4: The JFET cascode circuit of Aspect 2, wherein the gate driver is configured to, during the on-condition, set the voltage-controlled transistor into a conduction mode such that the cascode node is at a lower potential than the JFET gate potential, to cause the gate-source voltage to be sufficient to set the JFET into a conduction mode, wherein the JFET includes a gate-to-source pn junction, and wherein the overdrive voltage circuit is configured to limit the controlled overdrive value to a positive value that is less than a knee voltage of the gate-to-source pn junction.

Aspect 5: The JFET cascode circuit of any of Aspects 1-4, wherein the gate driver is configured to, during the off-condition, set the voltage-controlled transistor into the blocking mode such that: the cascode node is at the higher potential than the controlled overdrive value, and the gate-source voltage is sufficiently negative to set the JFET into the blocking mode.

Aspect 6: The JFET cascode circuit of any of Aspects 1-5, wherein the JFET includes a gate-to-source pn junction, and wherein the controlled overdrive value is a positive value that is less than a knee voltage of the gate-to-source pn junction.

Aspect 7: The JFET cascode circuit of Aspect 6, wherein the controlled overdrive value is a voltage level at which a drain-to-source on resistance of the JFET is minimized without the voltage level exceeding the knee voltage of the gate-to-source pn junction.

Aspect 8: The JFET cascode circuit of Aspect 6, wherein the overdrive voltage circuit is configured to, during the on-condition and the off-condition, bias the JFET gate terminal according to the controlled overdrive value.

Aspect 9: The JFET cascode circuit of Aspect 6, wherein the JFET includes a gate-to-source pn junction formed by a gate and a source of the JFET, and wherein the overdrive voltage circuit is configured to, during the on-condition, limit a forward current flowing into the gate-to-source pn junction to a predefined value.

Aspect 10: The JFET cascode circuit of any of Aspects 1-9, wherein the overdrive voltage circuit is a voltage divider configured to continuously provide the controlled overdrive value during the on-condition and the off-condition, leading to a permanent positive bias at the JFET gate terminal during the on-condition and the off-condition.

Aspect 11: The JFET cascode circuit of any of Aspects 1-10, wherein the overdrive voltage circuit is a voltage regulator configured to continuously provide the controlled overdrive value during the on-condition and the off-condition, leading to a permanent positive bias at the JFET gate terminal during the on-condition and the off-condition.

Aspect 12: The JFET cascode circuit of any of Aspects 1-11, wherein the reference terminal is coupled to a common source node of the JFET cascode circuit, at which the reference potential is provided, the common source node corresponding to a source terminal of the voltage-controlled transistor.

Aspect 13: The JFET cascode circuit of any of Aspects 1-12, wherein the gate driver includes a first gate drive terminal and a second gate drive terminal, the first gate drive terminal and the second gate drive terminal being coupled to the transistor gate terminal, and wherein the gate driver is configured to source the first gate drive signal from the first gate drive terminal to the transistor gate terminal during the on-condition, and sink the second gate drive signal from the transistor gate terminal to the second gate drive terminal during the off-condition.

Aspect 14: The JFET cascode circuit of any of Aspects 1-13, wherein the overdrive voltage circuit includes a transformer configured to supply the gate driver according to the unipolar supply scheme, wherein the transformer includes a primary side coil and a secondary side coil, and wherein the supply terminal, the reference terminal, and the output terminal are coupled to the secondary side coil, with the output terminal being coupled to the secondary side coil at a middle tap position between the supply terminal and the reference terminal.

Aspect 15: A JFET cascode circuit, comprising: a gate driver configured to be supplied according to a unipolar supply scheme including a supply potential, sufficient for satisfying a controlled overdrive voltage, and a reference potential, the gate driver configured to generate gate drive signals, including a first gate drive signal during an on-condition and a second gate drive signal during an off-condition; a JFET having a JFET gate terminal configured to control a conduction of current through the JFET according to a gate-source voltage; a voltage-controlled transistor coupled, at a cascode node, to the JFET in a cascode configuration, the voltage-controlled transistor including a transistor gate terminal coupled to the gate driver, and configured to control a conduction of current through the voltage-controlled transistor based on the first gate drive signal or the second gate drive signal; and an overdrive voltage circuit that includes a supply terminal at which the supply potential is provided, a reference terminal at which the reference potential is provided, and an output terminal coupled to the JFET gate terminal and from which the controlled overdrive voltage is provided, wherein the overdrive voltage circuit is configured to set the controlled overdrive voltage to a predetermined amount of the supply potential, and wherein the cascode node is configured to, during the off-condition, float to a higher potential than a JFET gate potential of the JFET, to set the JFET into a blocking mode.

Aspect 16: A junction field effect transistor (JFET) cascode control circuit configured to control a JFET cascode circuit comprising a voltage-controlled transistor coupled to a JFET in a cascode configuration, the JFET cascode control circuit comprising: a gate driver configured to be supplied according to a unipolar supply scheme including a supply potential, sufficient for satisfying a controlled overdrive value, and a reference potential, the gate driver configured to generate gate drive signals based on a control signal, including a first gate drive signal during an on-condition and a second gate drive signal during an off-condition, and to output the first gate drive signal or the second gate drive signal at a gate drive terminal configured to be coupled to transistor gate terminal of the voltage-controlled transistor; an overdrive voltage circuit that includes a supply terminal at which the supply potential is provided, a reference terminal at which the reference potential is provided, and an output terminal configured to be coupled to a JFET gate terminal of the JFET, wherein the overdrive voltage circuit is configured to generate the controlled overdrive value as a fraction of the supply potential, and output the controlled overdrive value from the output terminal to the JFET gate terminal.

Aspect 17: The JFET cascode control circuit of Aspect 16, wherein the overdrive voltage circuit includes a transformer configured to supply the gate driver according to the unipolar supply scheme, wherein the transformer includes a primary side coil and a secondary side coil, and wherein the supply terminal, the reference terminal, and the output terminal are coupled to the secondary side coil, with the output terminal being coupled to the secondary side coil at a middle tap position between the supply terminal and the reference terminal.

Aspect 18: The JFET cascode control circuit of any of Aspects 16 or 17, wherein the overdrive voltage circuit is a voltage divider configured to continuously provide the controlled overdrive value during the on-condition and the off-condition, leading to a permanent positive bias at the JFET gate terminal during the on-condition and the off-condition.

Aspect 19: The JFET cascode control circuit of any of Aspects 16-18, wherein the overdrive voltage circuit is a voltage regulator configured to continuously provide the controlled overdrive value during the on-condition and the off-condition, leading to a permanent positive bias at the JFET gate terminal during the on-condition and the off-condition.

Aspect 20: A system configured to perform one or more operations recited in one or more of Aspects 1-19.

Aspect 21: An apparatus comprising means for performing one or more operations recited in one or more of Aspects 1-19.

Aspect 22: A non-transitory computer-readable medium storing a set of instructions, the set of instructions comprising one or more instructions that, when executed by a device, cause the device to perform one or more operations recited in one or more of Aspects 1-19.

Aspect 23: A computer program product comprising instructions or code for executing one or more operations recited in one or more of Aspects 1-19.

The foregoing disclosure provides illustration and description, but is not intended to be exhaustive or to limit the implementations to the precise form disclosed. Modifications and variations may be made in light of the above disclosure or may be acquired from practice of the implementations.

Some implementations may be described herein in connection with thresholds. As used herein, “satisfying” a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

As used herein, the term “component” is intended to be broadly construed as hardware, firmware, or a combination of hardware and software. Systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code-it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein, refers to any of the foregoing structures or any other structure suitable for implementation of the techniques described herein. Software may be stored on a non-transitory computer-readable medium such that the non-transitory computer readable medium includes program code or a program algorithm stored thereon that, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal, further information. “Signal conditioning,” as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation, and any other processes required to make a signal suitable for processing after conditioning.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a and b, a and c, b and c, and a, b, and c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

1. A junction field effect transistor (JFET) cascode circuit, comprising:
a gate driver configured to be supplied according to a unipolar supply scheme including a supply potential, sufficient for satisfying a controlled overdrive value, and a reference potential, the gate driver configured to generate gate drive signals, including a first gate drive signal during an on-condition and a second gate drive signal during an off-condition;
a JFET having a JFET gate terminal configured to control a conduction of current through the JFET according to a gate-source voltage;
a voltage-controlled transistor coupled, at a cascode node, to the JFET in a cascode configuration, the voltage-controlled transistor including a transistor gate terminal coupled to the gate driver, and configured to control a conduction of current through the voltage-controlled transistor based on the first gate drive signal or the second gate drive signal; and
an overdrive voltage circuit that includes a supply terminal at which the supply potential is provided, a reference terminal at which the reference potential is provided, and an output terminal coupled to the JFET gate terminal,
wherein the overdrive voltage circuit is configured to generate the controlled overdrive value as a fraction of the supply potential, and output the controlled overdrive value from the output terminal to the JFET gate terminal, and
wherein the cascode node is configured to, during the off-condition, float to a higher potential than a JFET gate potential of the JFET, to set the JFET into a blocking mode.

2. The JFET cascode circuit of claim 1, wherein the JFET includes a gate-to-source pn junction, and
wherein the controlled overdrive value is a positive value that is less than a knee voltage of the gate-to-source pn junction.

3. The JFET cascode circuit of claim 2, wherein the controlled overdrive value is a voltage level at which a drain-to-source on resistance of the JFET is minimized without the voltage level exceeding the knee voltage of the gate-to-source pn junction.

4. The JFET cascode circuit of claim 2, wherein the overdrive voltage circuit is configured to, during the on-condition and the off-condition, bias the JFET gate terminal according to the controlled overdrive value.

5. The JFET cascode circuit of claim 2, wherein the JFET includes a gate-to-source pn junction formed by a gate and a source of the JFET, and
wherein the overdrive voltage circuit is configured to, during the on-condition, limit a forward current flowing into the gate-to-source pn junction to a predefined value.

6. The JFET cascode circuit of claim 1, wherein the reference terminal is coupled to a common source node of the JFET cascode circuit, at which the reference potential is provided, the common source node corresponding to a source terminal of the voltage-controlled transistor.

7. The JFET cascode circuit of claim 1, wherein the overdrive voltage circuit includes a transformer configured to supply the gate driver according to the unipolar supply scheme,
wherein the transformer includes a primary side coil and a secondary side coil, and
wherein the supply terminal, the reference terminal, and the output terminal are coupled to the secondary side coil, with the output terminal being coupled to the secondary side coil at a middle tap position between the supply terminal and the reference terminal.

8. The JFET cascode circuit of claim 1, wherein the overdrive voltage circuit is a voltage divider configured to continuously provide the controlled overdrive value during the on-condition and the off-condition, leading to a permanent positive bias at the JFET gate terminal during the on-condition and the off-condition.

9. The JFET cascode circuit of claim 1, wherein the overdrive voltage circuit is a voltage regulator configured to continuously provide the controlled overdrive value during the on-condition and the off-condition, leading to a permanent positive bias at the JFET gate terminal during the on-condition and the off-condition.

10. A junction field effect transistor (JFET) cascode circuit, comprising:
a gate driver configured to be supplied according to a unipolar supply scheme including a supply potential, sufficient for satisfying a controlled overdrive voltage, and a reference potential, the gate driver configured to generate gate drive signals, including a first gate drive signal during an on-condition and a second gate drive signal during an off-condition;
a JFET having a JFET gate terminal configured to control a conduction of current through the JFET according to a gate-source voltage;
a voltage-controlled transistor coupled, at a cascode node, to the JFET in a cascode configuration, the voltage-controlled transistor including a transistor gate terminal coupled to the gate driver, and configured to control a conduction of current through the voltage-controlled transistor based on the first gate drive signal or the second gate drive signal; and
an overdrive voltage circuit that includes a supply terminal at which the supply potential is provided, a reference terminal at which the reference potential is provided, and an output terminal coupled to the JFET gate terminal and from which the controlled overdrive voltage is provided,
wherein the overdrive voltage circuit is configured to set the controlled overdrive voltage to a predetermined amount of the supply potential, and
wherein the cascode node is configured to, during the off-condition, float to a higher potential than a JFET gate potential of the JFET, to set the JFET into a blocking mode.

11. A junction field effect transistor (JFET) cascode control circuit configured to control a JFET cascode circuit comprising a voltage-controlled transistor coupled to a JFET in a cascode configuration, the JFET cascode control circuit comprising:
a gate driver configured to be supplied according to a unipolar supply scheme including a supply potential, sufficient for satisfying a controlled overdrive value, and a reference potential, the gate driver configured to generate gate drive signals based on a control signal, including a first gate drive signal during an on-condition and a second gate drive signal during an off-condition, and to output the first gate drive signal or the second gate drive signal at a gate drive terminal configured to be coupled to transistor gate terminal of the voltage-controlled transistor; and
an overdrive voltage circuit that includes a supply terminal at which the supply potential is provided, a reference terminal at which the reference potential is provided, and an output terminal configured to be coupled to a JFET gate terminal of the JFET,
wherein the overdrive voltage circuit is configured to generate the controlled overdrive value as a fraction of the supply potential, and output the controlled overdrive value from the output terminal to the JFET gate terminal.

12. The JFET cascode control circuit of claim 11, wherein the overdrive voltage circuit includes a transformer configured to supply the gate driver according to the unipolar supply scheme,
wherein the transformer includes a primary side coil and a secondary side coil, and
wherein the supply terminal, the reference terminal, and the output terminal are coupled to the secondary side coil, with the output terminal being coupled to the secondary side coil at a middle tap position between the supply terminal and the reference terminal.

13. The JFET cascode control circuit of claim 11, wherein the overdrive voltage circuit is a voltage divider configured to continuously provide the controlled overdrive value during the on-condition and the off-condition, leading to a permanent positive bias at the JFET gate terminal during the on-condition and the off-condition.

14. The JFET cascode control circuit of claim 11, wherein the overdrive voltage circuit is a voltage regulator configured to continuously provide the controlled overdrive value during the on-condition and the off-condition, leading to a permanent positive bias at the JFET gate terminal during the on-condition and the off-condition.
